(19) United States
(12) Patent Application Publication
(10) Pub. No.: US 2015/0179849 A1
(43) Pub. Date: Jun. 25, 2015

(54) SOLAR CELL MODULE

(71) Applicant: SANYO Electric Co., Ltd., Osaka (JP)

(72) Inventors: Tasuku ISHIGURO, Osaka (JP); Masanori MAEDA, Hyogo (JP)

(21) Appl. No.: 14/630,735

(22) Filed: Feb. 25, 2015

Related U.S. Application Data
(63) Continuation of application No. PCT/JP2012/071674, filed on Aug. 28, 2012.

(51) Int. Cl. H01L 31/048; H01L 31/02

(52) U.S. Cl. CPC H01L 31/048; H01L 31/02013

(57) ABSTRACT

Disclosed is a solar cell that includes a sealant, a solar cell within the sealant and having a front surface for exposure to light, a first protective member facing a front surface of the solar cell, a second protective member facing a rear surface of the solar cell, a wiring member on a rear surface of the solar cell and containing Cu. The sealant includes a first sealant layer over the rear surface of the solar cell and having relatively high viscosity, and a second sealant layer disposed between the first sealant layer and the solar cell and having relatively low viscosity. The first sealant layer disposed on a side of second protective member is in contact with a main surface of the wiring member, and the second sealant layer is in contact with a side surface of the wiring member.

### CROSS REFERENCE TO RELATED APPLICATIONS

This application is a continuation application of International Application No. PCT/JP2012/071674, filed on Aug. 28, 2012, entitled “SOLAR CELL MODULE”, the entire contents of which are incorporated herein by reference.

### TECHNICAL FIELD

The invention relates to solar cell modules having sealant layers.

### BACKGROUND ART

A solar cell module having solar cells within a sealant layer disposed between a light-receiving surface side protective member and a back surface side protective member is conventional. For example, Japanese Patent Application Publication No. 2003-258283 (“patent document 1”) states that a portion of a sealant layer located between a solar cell and a light-receiving surface side protective member is formed of a transparent ethylene vinyl acetate copolymer (EVA) film, and a portion thereof located between a solar cell and a back surface side protective member is formed of a colored EVA film. Patent Document 1 states that output characteristics of the solar cell module can be improved by using a colored EVA film.

### SUMMARY

A solar cell module described in Patent Document 1 has a problem wherein output characteristics are likely to vary over time.

A solar cell module according to embodiments includes a sealant, a solar cell within the sealant and having a front surface for exposure to light, a first protective member facing a front surface of the solar cell, a second protective member facing a rear surface of the solar cell, a wiring member on a rear surface of the solar cell and containing Cu. The sealant includes a first sealant layer over the rear surface of the solar cell and having relatively high viscosity, and a second sealant layer disposed between the first sealant layer and the solar cell and having relatively low viscosity. The first sealant layer disposed on a side of second protective member is in contact with a main surface of the wiring member, and the second sealant layer is in contact with a side surface of the wiring member.

### BRIEF DESCRIPTION OF THE DRAWINGS

FIG. 1 is a schematic plan view of a solar cell module according to an embodiment.

FIG. 2 is a schematic cross-sectional view of the solar cell module according to an embodiment.

FIG. 3 is a schematic cross-sectional view of a portion III in FIG. 2.

FIG. 4 is a schematic cross-sectional view of a portion of a solar cell module according to a first modification.

FIG. 5 is a schematic cross-sectional view of a portion of a solar cell module according to a second modification.

FIG. 6 is a schematic cross-sectional view of a portion of a solar cell module according to a third modification.

FIG. 7 is a schematic exploded cross-sectional view of a laminate according to an embodiment.

### DETAILED DESCRIPTION

Hereinafter, embodiments are described. Note that the embodiment described below is merely illustrative, and the invention is not limited to the embodiment described below in any way.

In the drawings referred to for the embodiment and the like, a member having substantially the same function is referred to with the same reference numeral. The drawings referred to for the embodiment and the like are schematically illustrated, and the dimension ratio and the like of an object drawn in the drawings may be different from those of a real object. The dimension ratio and the like of an object may be different between the drawings. The dimension ratio and the like of a specific object should be determined by considering description given below.

As illustrated in FIG. 2, solar cell module 1 includes first protective member 11 and second protective member 16. First protective member 11 may be formed of, for example, a glass sheet. Second protective member 16 faces first protective member 11 at a distance. Second protective member 16 is formed of, for example, a resin sheet made of polyethylene terephthalate (PET), polyvinyl fluoride resin (PVF), polyvinylidene fluoride (PVDF), or a combination thereof or the like. Second protective member 16 may be made of a resin sheet, or a resin sheet including a barrier layer such as a metal layer and an inorganic oxide layer. The oxygen permeability of second protective member 16 is higher than the oxygen permeability of first protective member 11.

Sealant 17 is disposed between first protective member 11 and second protective member 16. Specifically, sealant 17 is held by and between first protective member 11 provided on one side, and second protective member 16 provided on the other side. Solar cell 13 is disposed within the sealant 17. Solar cell 13 is disposed in such a manner that light-receiving surface 13a as a first main surface is oriented toward first protective member 11, and back surface 13b as a second main surface is oriented toward second protective member 16. Note that light-receiving surface 13a is one of the first and second main surfaces of solar cell 13, that has relatively high amount of incident light, and back surface 13b is one that has relatively low amount of incident light.

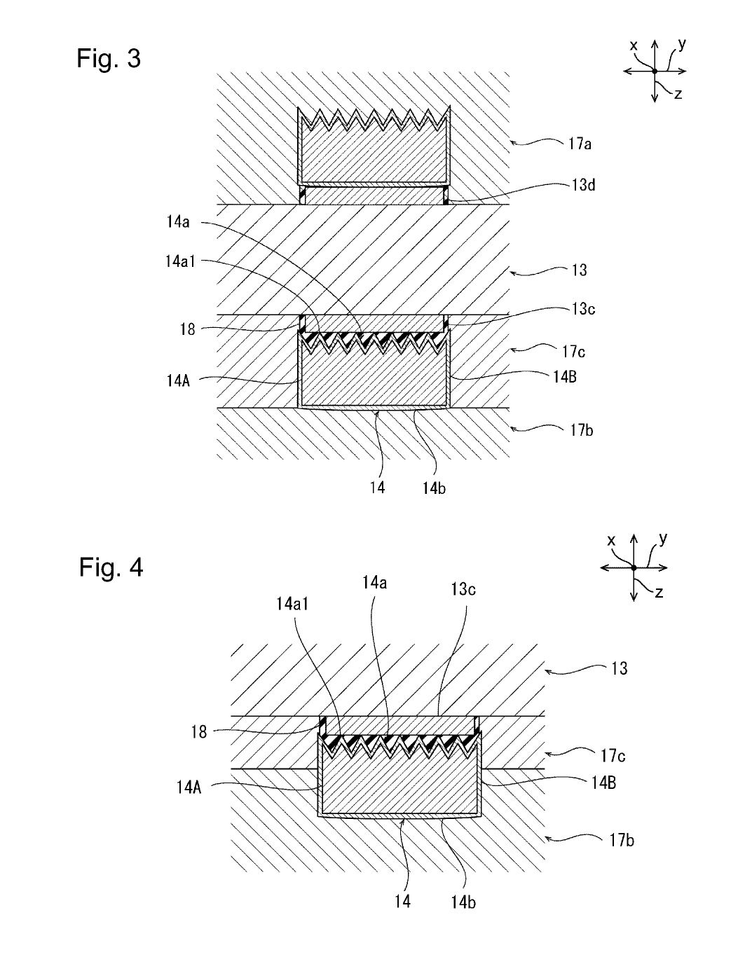

Solar cell 13 includes first electrode 13d (see FIG. 3) disposed on light-receiving surface 13a, and second electrode 13c disposed on back surface 13b. However, in the invention, the solar cell may be a back contact solar cell in which both first and second electrodes are disposed on one main surface (typically, back surface).

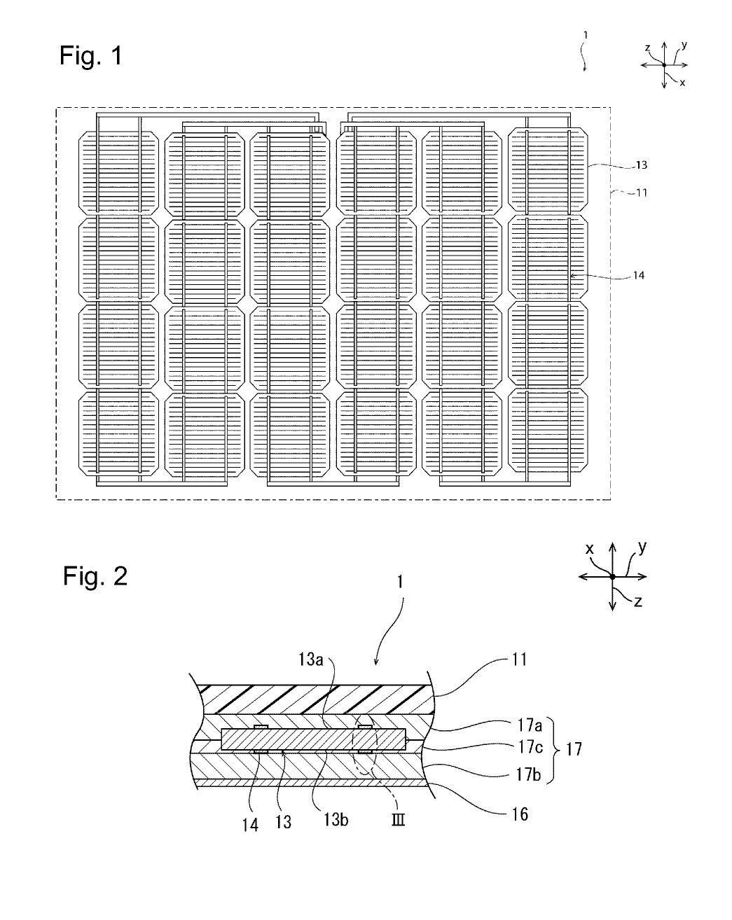

As illustrated in FIG. 1, solar cell module 1 includes a plurality of solar cells 13. The plurality of solar cells are electrically connected to each other by metallic wiring member 14. Specifically, first electrode 13d of one solar cell out of adjacent solar cells 13 and second electrode 13c of the other solar cell are electrically connected to each other by wiring member 14.

As illustrated in FIG. 3, wiring member 14 and solar cell 13 are bonded to each other by resin adhesive layer 18 containing a cured resin adhesive. Resin adhesive layer 18 may be formed of, for example, a resin only. In this case, wiring member 14 is preferably bonded by resin adhesive layer 18 while in contact with an electrode of solar cell 13. Resin adhesive layer 18 may be formed of, for example, a resin containing a conductive material. In this case, wiring member 14 and solar cell 13 may be electrically connected by the conductive material.

Wiring member 14 contains Cupper (Cu). Specifically, wiring member 14 includes wiring member body 14A and coating layer 14B. Wiring member body 14A of wiring member 14 is made of copper or copper alloy. Specific examples of the copper alloy include, for example, a Cu—Fe—Ni alloy and the like. Wiring member body 14A is coated with coating layer 14B. Coating layer 14B does not contain Copper (Cu) substantially. Coating layer 14B may be formed of, for example, silver or a silver alloy. Specific examples of the silver alloy include, for example, Ag—Bi alloy and the like. Thickness of coating layer 14B may be, for example, about 0.1 μm to 100 μm.

Wiring member 14 includes first main surface 14a and second main surface 14b. Wiring member 14 is disposed in such a manner that first main surface 14a is oriented toward first protective member 11 and second main surface 14b is oriented toward second protective member 16. Accordingly, second main surface 14b of wiring member 14 and solar cell face each other on first protective member 11 side relative to solar cell 13. First main surface 14a of wiring member 14 and solar cell 13 face each other on second protective member 16 side relative to solar cell 13.

Irregularities 14a1 are provided on first main surface 14a. Specifically, a plurality of irregularities 14a1 extending in a direction where wiring member 14 extends is provided on first main surface 14a. For this reason, light passing through first protective member 11 and incident on wiring member 14 is irregularly reflected on first main surface 14a and efficiently guided onto light-receiving surface 13a of solar cell 13. Size of apex angle in a transverse section of irregularity 14a1 is preferably, for example, about 120° to 150°.

On the other hand, second main surface 14b is formed of a flat surface. Here, the flat surface means a surface not having a plurality of irregularities. The flat surface includes, for example, a convex surface or a concave surface curved with a curvature radius larger than the width of wiring member 14.

Wiring member 14 having first main surface 14a including irregularities may be fabricated, for example, by pressing a flat plate-shaped base material having flat main surfaces on both sides thereof. In general, in wiring member 14 fabricated by pressing, thickness of portions of coating layer 14B above corner portions of wiring member body 14A is thinner than the other portions. The thickness of portions of coating layer 14B above corner portions of wiring member body 14A is often less than ½ of the thickness of the other portions thereof.

Sealant 17 may be formed of, for example, a crosslinkable resin such as ethylene vinyl acetate copolymer (EVA) or a non-crosslinkable resin such as polyolefin. Sealant 17 includes sealant layer 17a, sealant layer 17b, and sealant layer 17c. Sealant layer 17a, sealant layer 17c, and sealant layer 17b are disposed in this order from the side of first protective member 11 toward the side of second protective member 16.

Sealant layer 17a is disposed between first protective member 11 and solar cell 13. Sealant layer 17a is in contact with a surface of first protective member 11 on the side of solar cell 13, and light-receiving surface 13a of solar cell 13. Sealant layer 17a may or may not cover at least a portion of a side face of solar cell 13.

Sealant layer 17b is disposed between solar cell 13 and second protective member 16. Sealant layer 17b is disposed above back surface 13b of solar cell 13. Sealant layer 17b is in contact with a surface of second protective member 16 on the side of solar cell 13. Sealant layer 17b is not in contact with back surface 13b of solar cell 13.

Sealant layer 17c is disposed between sealant layer 17b and solar cell 13. Sealant layer 17c is in contact with a surface of sealant layer 17b on the side of solar cell 13, and back surface 13b of solar cell 13.

Sealant layer 17b contains inorganic filler, while sealant layer 17c does not contain inorganic filler. For this reason, sealant layer 17b has relatively high viscosity, and sealant 17c has relatively low viscosity. In other words, the viscosity of sealant layer 17b is higher than the viscosity of sealant layer 17c. Specifically, sealant layer 17b includes, for example, colored particles such as white particles of titanium dioxide as the inorganic filler. For this reason, sealant layer 17b is formed of a colored resin, and sealant layer 17c is formed of a transparent resin. Sealant layer 17b needs not to necessarily include inorganic filler. Sealant layer 17b may be a layer formed of a transparent resin.

In embodiments, the viscosity of sealant layer 17a may be, for example, equal to or higher than the viscosity of sealant layer 17b, may be between the viscosity of sealant layer 17b and the viscosity of sealant layer 17c, or may be equal to or lower than the viscosity of sealant layer 17c.

Meanwhile, the entire portion of the sealant layer located between the solar cell and the second protective member may be formed of a highly viscous colored filler material layer containing inorganic filler. In this case, however, a portion of the wiring member located on the back surface of the solar cell is covered with the highly viscous colored filler material layer. For this reason, when temperature of the solar cell module changes, large stress is likely to be applied between the wiring member and the solar cell. Accordingly, series resistance of the solar cell module may deteriorate over time, resulting in deterioration of output characteristics.

In view of the foregoing, it is considered to lower the viscosity of a portion of the sealant located between the solar cell and the second protective member. In this case, however, a portion of the sealant located in the vicinity of corner portions of the second protective member of the wiring member is likely to be discolored over time. The discoloration of the sealant may be possibly caused by dispersion of copper contained in the wiring member into the sealant due to oxygen existing in the sealant. Thus, it is considered that the sealant is easily discolored by lowering the viscosity of the sealant, which results in easy dispersion of copper. Discoloration of the sealant enhances light absorption rate in the sealant and thereby reduces light utilization efficiency. As a result, output characteristics of the solar cell module deteriorate.

Here, in solar cell module 1, sealant layer 17b is disposed in contact with second main surface 14b of wiring member 14. Since sealant layer 17b has relatively high viscosity, copper is unlikely to disperse into sealant layer 17b. Therefore, sealant layer 17b is unlikely to be discolored. Furthermore, sealant layer 17c having relatively low viscosity is disposed to be in contact with a side surface of wiring member 14. For this reason, even when the temperature of solar cell module 1 changes, stress is unlikely to be applied between solar cell 13 and wiring member 14. Therefore, series resistance of solar cell module 1 is unlikely to deteriorate over time. Accordingly, a solar cell module with output characteristics unlikely to deteriorate over time can be achieved.

In the light of further suppressing change-over-time of output characteristics, the viscosity of sealant layer 17b is preferably equal to or higher than 1.5 times the viscosity of sealant layer 17c, and more preferably, equal to or higher than 3 times the viscosity of sealant layer 17c. However, too high viscosity of sealant layer 17b increases probability of deflecting the sealant layer 17b and thereby causing cell cracks. Accordingly, the viscosity of sealant layer 17b is preferably equal to or lower than 10 times the viscosity of sealant layer 17c, and more preferably equal to or lower than 5 times the viscosity of sealant layer 17c. Specifically, the viscosity of sealant layer 17b is preferably 10^{5.5} Pa to 10⁷ Pa, and more preferably 10⁶ Pa to 10^{6.5} Pa. The viscosity of sealant layer 17c is preferably 10⁵ Pa to 10^{6.5} Pa, and more preferably 10^{5.5} Pa to 10⁶ Pa. The viscosity of the sealant layer is a E″ (E double prime) viscosity component according to the dynamic viscoelasticity measurement. The viscosity of the sealant layer can be measured under the following conditions by using a viscoelastic spectrometer.

Temperature rising rate: 20° C./min.

Measured temperature region: 60° C.

Atmosphere: air (feeding at flow rate of 200 mL/min.)

Measuring frequency: 1 Hz

Distortion amplitude: 5 μm

Min. tension/min. compressive force: 100 mN

Tension gain/compressive force gain: 1.2

Initial value of force amplitude: 200 mN

Size of sample: Length 5 mm×Height 10 mm×Width 0.6 mm.

In the light of suppressing deterioration of output characteristics of solar cell module 1 over time, sealant layer 17b may be in contact with second main surface 14b of wiring member 14. In solar cell module 1, second main surface 14b and a surface of sealant layer 17b are substantially flush with each other. However, for example, as illustrated in FIG. 4, a portion of wiring member 14 may be located within sealant layer 17b. In other words, corner portions of wiring member 14 on the side of second main surface 14b may be located within sealant layer 17b. In this case, discoloration of sealant 17 can be effectively suppressed.

As described above, existence of oxygen is a possible cause of the discoloration of sealant 17. For this reason, discoloration of sealant 17 is unlikely to occur on the side of first protective member 11 made of glass and having low oxygen permeability, while discoloration of sealant 17 is likely to occur on the side of second protective member 16 formed of a resin sheet and having high oxygen permeability. In particular, discoloration of sealant 17 is more likely to occur on the side of second protective member 16 when second protective member 16 is formed of a resin sheet not having a barrier layer such as a metal layer and an inorganic oxide layer. Accordingly, it is preferable that sealant layer 17b having relatively high viscosity be disposed on the side of second protective member 16.

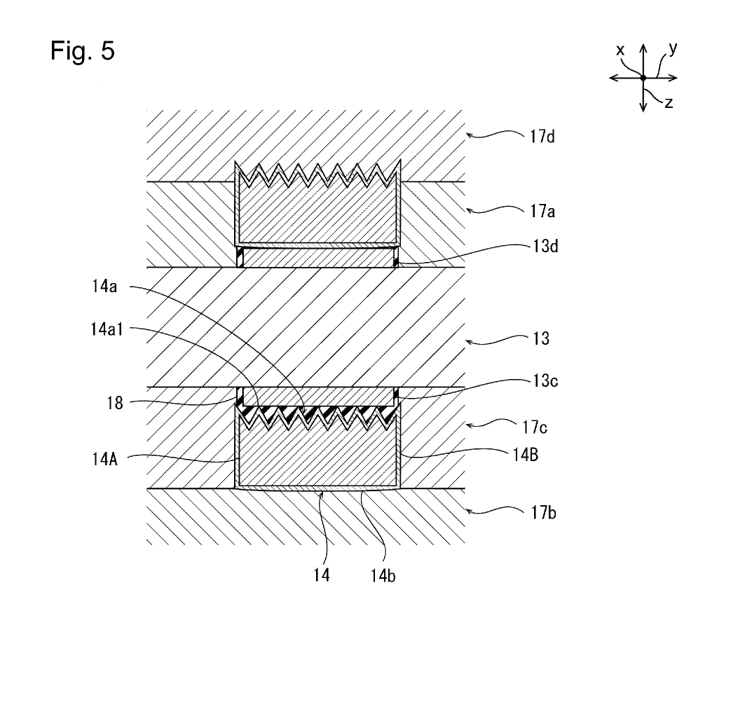

In solar cell module 1 described above, sealant layer 17b having relatively high viscosity is provided on the side of second protective member 16 only. However, for example, sealant layer 17d having relatively high viscosity may be provided on the side of first protective member 11 as illustrated in FIG. 5.

In a modification illustrated in FIG. 5, sealant layer 17d is disposed between sealant layer 17a and first protective member 11. The viscosity of sealant layer 17d is higher than the viscosity of sealant layer 17a. Sealant layer 17d having relatively high viscosity is disposed to be in contact with first main surface 14a of wiring member 14. Sealant layer 17a having relatively low viscosity is disposed to be in contact with a side surface of wiring member 14. Sealant layer 17d may be disposed to cover corner portions of wiring member 14 on the side of first main surface 14a. In other words, a portion of wiring member 14 may be disposed within sealant layer 17d.

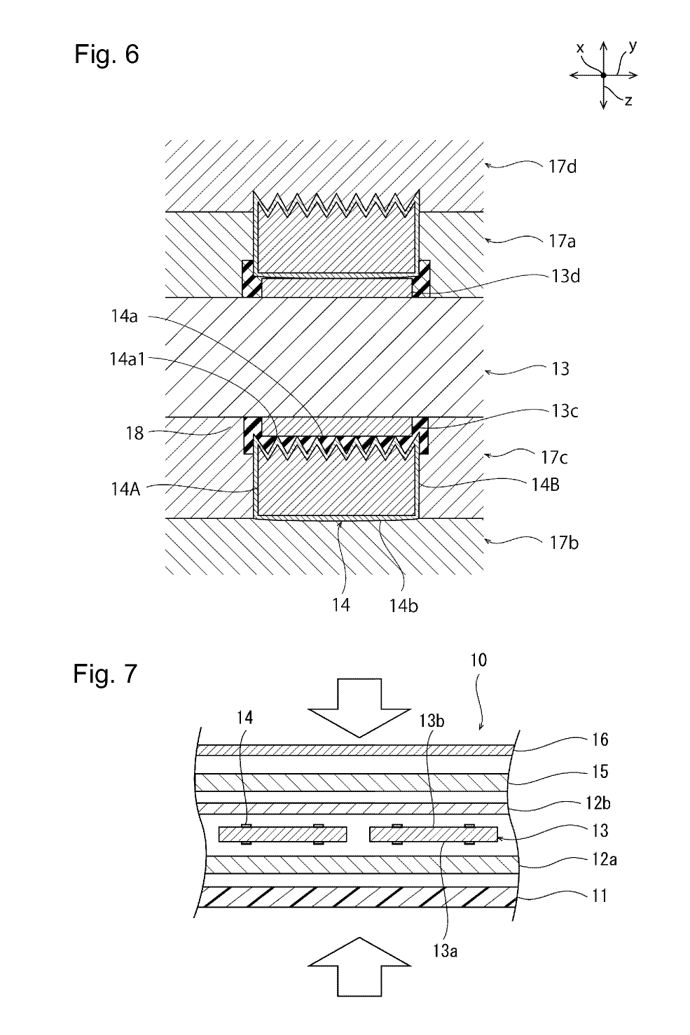

As illustrated in FIG. 6, resin adhesive layer 18 may be disposed with a wider width than that of wiring member 14. Corner portions of wiring member 14 on the side of solar cell 13 are preferably located within resin adhesive layer 18. In this case, since resin adhesive layer 18 has viscosity higher than sealant layers 17b, 17d, dispersion of copper into sealant 17 is effectively suppressed by resin adhesive layer 18. Accordingly, discoloration of sealant 17 is more effectively suppressed.

### (Method of Manufacturing Solar Cell Module 1)

Solar cell module 1 may be manufactured, for example, according to the following procedure. Firstly, a laminate illustrated in FIG. 7 is fabricated. Specifically, laminate is fabricated by stacking first protective member 11, resin sheet 12a, solar cell 13 with wiring member 14, resin sheet 12b, resin sheet 15, and second protective member 16 in this order. Resin sheet 12a is a resin sheet for forming sealant layer 17a. Resin sheet 12b is a resin sheet for forming sealant layer 17c. Resin sheet 15 is a resin sheet for forming sealant layer 17b.

Next, laminate 10 is pressurized while being heated (heating press process). Thus, solar cell module 1 can be completed. In the heating press process, transparent resin sheet 12b is disposed between resin sheet 15 and solar cell 13 to suppress flowing of resin sheet 15 formed of a colored resin onto light-receiving surface 13a of solar cell 13.

In the heating press process, heating temperature of laminate 10 may be, for example, about 100° C. to 160° C., and is preferably about 130° C. to 150° C. Heating temperature of laminate 10 may be, for example, about 125° C.

According to embodiments described above, a solar cell module with output characteristics unlikely to vary over time can be provided.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A solar cell module comprising:
a sealant;
a solar cell within the sealant and having a front surface for exposure to light;
a first protective member facing a front surface of the solar cell;
a second protective member facing a rear surface of the solar cell;
a wiring member on a rear surface of the solar cell and containing Cu, wherein
the sealant includes:
a first sealant layer over the rear surface of the solar cell and having relatively high viscosity; and
a second sealant layer disposed between the first sealant layer and the solar cell and having relatively low viscosity,
the first sealant layer disposed on a side of second protective member is in contact with a main surface of the wiring member, and
the second sealant layer is in contact with a side surface of the wiring member.

2. The solar cell module according to claim 1, wherein a portion of the wiring member is within the second sealant layer.

3. The solar cell module according to claim 1, further comprising:
a glass sheet on one side of the sealant; and
a resin sheet on the other side of the sealant, wherein
the first and second sealant layers are between the solar cell and the resin sheet.

4. The solar cell module according to claim 1, wherein the first sealant layer contains inorganic filler.

5. The solar cell module according to claim 1, wherein
the wiring member includes:
a wiring member body made of copper or a copper alloy; and
a coating layer covering the wiring member body and made of silver or a silver alloy.

6. The solar cell module according to claim 1, further comprising a resin adhesive layer bonding the solar cell and the wiring member to each other.

7. The solar cell module according to claim 1, wherein the first sealant layer is reflective.

8. The solar cell module according to claim 1, wherein the first sealant layer comprises titanium dioxide.

9. The solar cell module according to claim 1, wherein the first sealant layer has a viscosity of 10^{5.5} Pa to 10⁷ Pa and the second sealant layer has a viscosity of 10⁵ Pa to 10^{6.5} Pa.

10. The solar cell module according to claim 9, wherein the first sealant layer has a viscosity of 10⁶ Pa to 10^{6.5} Pa and the second sealant layer has a viscosity of 10^{5.5} Pa to 10⁶.
